(19) United States
(12) Patent Application Publication
(10) Pub. No.: US 2020/0312632 A1
(43) Pub. Date: Oct. 1, 2020

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Daisuke HARA, Toyama-shi (JP); Takashi YAHATA, Toyama-shi (JP); Tsuyoshi TAKEDA, Toyama-shi (JP); Kenji ONO, Toyama-shi (JP); Kazuhiko YAMAZAKI, Toyama-shi (JP)

(73) Assignee: KOKUSAI ELECTRIC CORPORATION, Tokyo (JP)

(21) Appl. No.: 16/815,284

(22) Filed: Mar. 11, 2020

(30) Foreign Application Priority Data
Mar. 25, 2019 (JP) 2019-056620

(51) Int. Cl. H01J 37/32; C23C 16/458; C23C 16/50; C23C 16/44

(52) U.S. Cl. CPC H01J 37/32568; H01J 37/32715; H01J 37/32541; H01J 37/3244; H01L 21/0217; C23C 16/4584; C23C 16/50; C23C 16/4408; H01J 37/32559

(57) ABSTRACT

There is provided a technique that includes: a reaction tube configured to process a plurality of substrates; a substrate support configured to support the plurality of substrates stacked in multiple stages; a buffer chamber that is at least located at a position of height from a lowermost substrate to an uppermost substrate supported by the substrate support, and is installed along an inner wall of the reaction tube; and an electrode for plasma generation that is inserted from a lower portion of the buffer chamber into an upper portion of the buffer chamber through a side surface of the reaction tube, the electrode being configured to activate the processing gas by plasma inside the buffer chamber thereby applying high-frequency power to the electrode by a power supply.

### CROSS-REFERENCE TO RELATED APPLICATION(S)

This application is based upon and claims the benefit of priority from Japanese Patent Application No. 2019-056620, filed on Mar. 25, 2019, the entire contents of which are incorporated herein by reference.

### TECHNICAL FIELD

The present disclosure relates to a substrate processing apparatus, a method of manufacturing a semiconductor device, and a recording medium.

### BACKGROUND

As a semiconductor-device-manufacturing process, a substrate-processing process is often carried out in which a precursor gas, a reaction gas, and so on are activated by plasma and are supplied to a substrate accommodated in a process chamber of a substrate processing apparatus, so that various films such as an insulating film, a semiconductor film, a conductor film, and the like can be formed on the substrate or removed from the substrate.

However, depending on the configuration of a buffer chamber for generating plasma, a standing wave may be generated to make the plasma density non-uniform. When the plasma becomes non-uniform, the supply of active species gases to a wafer becomes unstable, which may cause problems in film thickness uniformity, wet etching rate (WER), and the like with respect to wafer film formation.

### SUMMARY

Some embodiments of the present disclosure provide a technique capable of processing a substrate uniformly.

According to one or more embodiments of the present disclosure, there is provided a technique that includes: a reaction tube configured to process a plurality of substrates; a substrate support configured to support the plurality of substrates stacked in multiple stages; a buffer chamber that is at least located at a position of height from a lowermost substrate to an uppermost substrate supported by the substrate support, and is installed along an inner wall of the reaction tube; and an electrode for plasma generation that is inserted from a lower portion of the buffer chamber into an upper portion of the buffer chamber through a side surface of the reaction tube, the electrode being configured to activate the processing gas by plasma inside the buffer chamber thereby applying high-frequency power to the electrode by a power supply.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in embodiments of the present disclosure, in which a portion of the process furnace is illustrated in a vertical cross-sectional view.

FIG. 2 is a schematic configuration view of the vertical process furnace of the substrate processing apparatus suitably used in embodiments of the present disclosure, in which a portion of the process furnace is illustrated in a cross-sectional view taken along the line A-A in FIG. 1.

FIG. 3A is an enlarged cross-sectional view for explaining a buffer structure of the substrate processing apparatus suitably used in embodiments of the present disclosure.

FIG. 3B is a schematic view for explaining the buffer structure of the substrate processing apparatus suitably used in embodiments of the present disclosure.

FIG. 4 is a schematic configuration diagram of a controller of the substrate processing apparatus suitably used in embodiments of the present disclosure, in which a control system of the controller is illustrated in a block diagram.

FIG. 5 is a flowchart of a substrate-processing process according to embodiments of the present disclosure.

FIG. 6 is a diagram showing gas supply timings in the substrate-processing process according to the embodiments of the present disclosure.

FIG. 7 is a schematic configuration view for explaining the effects of the substrate processing apparatus suitably used in embodiments of the present disclosure.

FIG. 8 is a schematic configuration view for explaining a substrate processing apparatus of a comparative example of the present disclosure.

FIG. 9 is a view for explaining a standing wave due to a traveling wave and a reflected wave of plasma.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

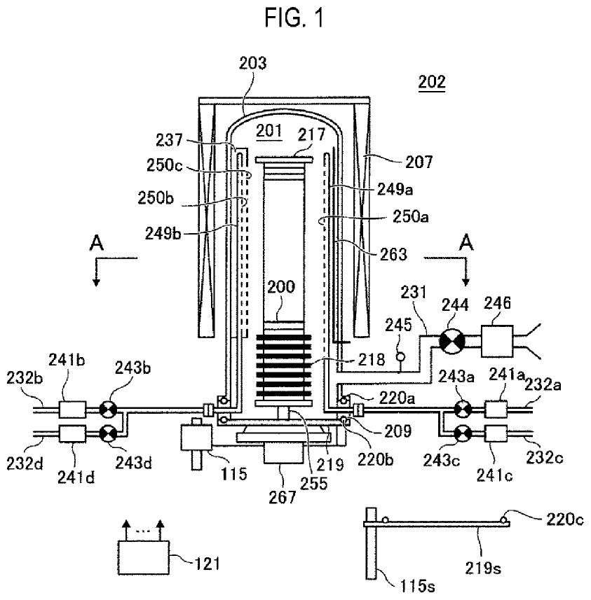

One or more embodiments of the present disclosure will now be described with reference to FIGS. 1 to 6.

### (1) Configuration of Substrate Processing Apparatus

As illustrated in FIG. 1, a process furnace 202 is a so-called vertical furnace in which substrates can be accommodated in multiple stages in the vertical direction, and includes a heater 207 as a heating device (a heating mechanism). The heater 207 has a cylindrical shape and is supported by a heat base (not shown) serving as a support plate so as to be vertically installed. As will be described below, the heater 207 functions as an activation mechanism (an excitation part) configured to thermally activate (excite) a gas.

### (Process Chamber)

A reaction tube 203 is disposed inside the heater 207 to be concentric with the heater 207. The reaction tube 203 is made of, for example, a heat resistant material such as quartz (SiO₂), silicon carbide (SiC), or the like, and has a cylindrical shape with its upper end closed and its lower end opened. A manifold (inlet flange) 209 is disposed to be concentric with the reaction tube 203 under the reaction tube 203. The manifold 209 is made of, for example, a metal material such as stainless steel (SUS: Steel Use Stainless) or the like, and has a cylindrical shape with both of its upper and lower ends opened. The upper end portion of the manifold 209 engages with the lower end portion of the reaction tube 203 so as to support the reaction tube 203. An O-ring 220a serving as a seal member is installed between the manifold 209 and the reaction tube 203. As the manifold 209 is supported by the heater base, the reaction tube 203 is in a state of being vertically installed. A process vessel (reaction vessel) mainly includes the reaction tube 203 and the manifold 209. A process chamber 201 is formed at a hollow cylindrical portion inside the process vessel (reaction vessel). The process chamber 201 is configured to accommodate a plurality of wafers 200 as substrates. Note that the process vessel is not limited to the above configuration, and only the reaction tube 203 may be referred to as the process vessel.

Nozzles 249a and 249b are installed in the process chamber 201 so as to penetrate through a sidewall of the manifold 209. Gas supply pipes 232a and 232b are connected to the nozzles 249a and 249b, respectively. In this way, the two nozzles 249a and 249b and the two gas supply pipes 232a and 232b are installed at the process furnace 202, thereby allowing plural kinds of gases to be supplied into the process chamber 201.

Mass flow controllers (MFCs) 241a and 241b, which are flow rate controllers (flow rate control parts), and valves 243a and 243b, which are opening/closing valves, are installed to the gas supply pipes 232a and 232b, respectively, sequentially from the upstream side of a gas flow. Gas supply pipes 232c and 232d for supplying an inert gas are connected to the gas supply pipes 232a and 232b at downstream sides of the valves 243a and 243b, respectively. MFCs 241c and 241d and valves 243c and 243d are installed to the gas supply pipes 232c and 232d, respectively, sequentially from the upstream side of a gas flow.

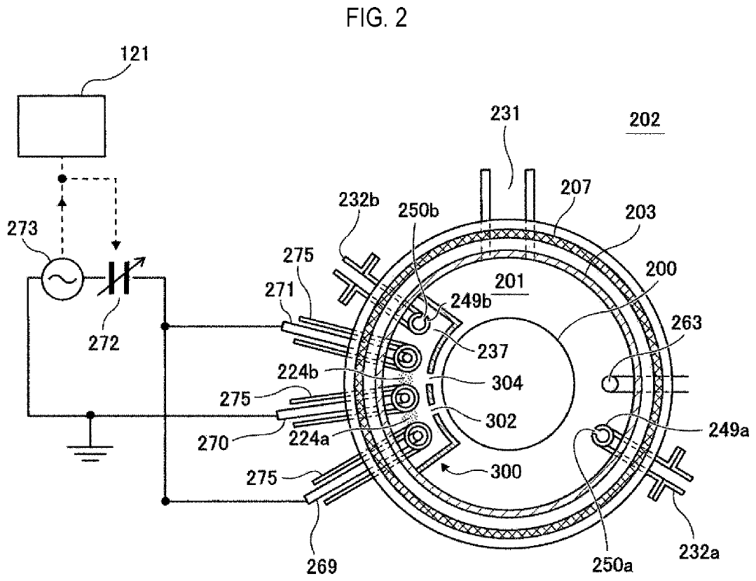

As illustrated in FIG. 2, the nozzle 249a is disposed at a space between an inner wall of the reaction tube 203 and the wafers 200 so as to extend upward along a stack direction of the wafers 200 from a lower portion of the inner wall of the reaction tube 203 to an upper portion thereof. Specifically, the nozzle 249a is installed at a region horizontally surrounding a wafer arrangement region (mounting region) in which the wafers 200 are arranged (mounted) at a lateral side of the wafer arrangement region, along the wafer arrangement region. That is, the nozzle 249a is installed in a perpendicular relationship with the surfaces (flat surfaces) of the wafers 200 at a lateral side of the end portions (peripheral edge portions) of the wafers 200, which are loaded into the process chamber 201. A gas supply hole 250a for supplying a gas is formed on the side surface of the nozzle 249a. The gas supply hole 250a is opened toward the center of the reaction tube 203 to allow the gas to be supplied toward the wafers 200. A plurality of gas supply holes 250a may be formed between the lower portion of the reaction tube 203 and the upper portion thereof. The plurality of gas supply holes 250a may be formed to have the same aperture area at the same aperture pitch.

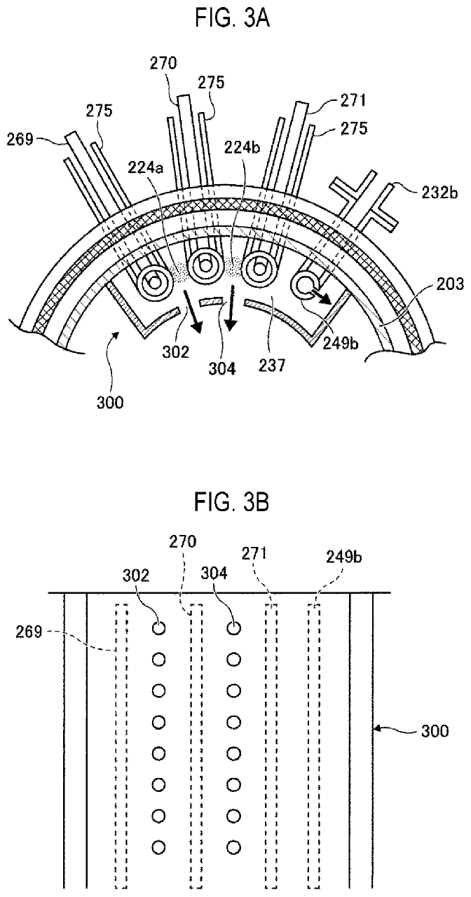

The nozzle 249b is connected to the leading end of the gas supply pipe 232b. The nozzle 249b is disposed in a buffer chamber 237 serving as a gas dispersion space. As illustrated in FIG. 2, the buffer chamber 237 is disposed at an annular space (in a plan view) between the inner wall of the reaction tube 203 and the wafers 200 such that the buffer chamber 237 extends upward along the stack direction of the wafers 200 from the lower portion of the inner wall of the reaction tube 203 to the upper portion thereof. More specifically, the buffer chamber 237 is formed along the inner wall of the reaction tube 203 at the height between the lowermost wafer 200 and the uppermost wafer 200 which are supported by a boat 217. That is, the buffer chamber 237 is formed by a buffer structure (partition wall) 300 along the wafer arrangement region in a region horizontally surrounding the wafer arrangement region at the lateral side of the wafer arrangement region. The buffer structure 300 is made of an insulating material which is a heat resistant material such as quartz, SiC, or the like. Gas supply ports 302 and 304 for supplying a gas are formed at an arc-shaped wall surface of the buffer structure 300. As illustrated in FIGS. 2, 3A, and 3B, the gas supply ports 302 and 304 are opened toward the center of the reaction tube 203 at positions facing plasma generation regions 224a and 224b between rod-shaped electrodes 269 and 270 (which will be described below) and between rod-shaped electrodes 270 and 271 (which will be described below), respectively, thereby allowing a gas to be supplied toward the wafers 200. A plurality of gas supply ports 302 and 304 may be formed between the lower portion of the reaction tube 203 and the upper portion thereof. The plurality of gas supply ports 302 and 304 may be formed to have the same aperture area at the same aperture pitch. The distance between the lowermost gas supply ports 302 and 304 and the bottom surface of the buffer chamber 237 is substantially equal to the distance between the uppermost gas supply ports 302 and 304 and the top surface of the buffer chamber 237.

The nozzle 249b is disposed so as to extend upward along the stack direction of the wafers 200 from the lower portion of the inner wall of the reaction tube 203 to the upper portion thereof. Specifically, the nozzle 249b is installed at a region horizontally surrounding the wafer arrangement region in which the wafers 200 are arranged at the lateral side of the wafer arrangement region inside the buffer structure 300, along the wafer arrangement region. That is, the nozzle 249b is installed in a perpendicular relationship with the surfaces of the wafers 200 at the lateral side of the end portions of the wafers 200, which are loaded into the process chamber 201. A gas supply hole 250b for supplying a gas is formed at the side surface of the nozzle 249b. The gas supply hole 250b is opened toward a wall surface formed in the radial direction with respect to the arc-shaped wall surface of the buffer structure 300, thereby allowing a gas to be supplied toward the wall surface. As a result, the reaction gas is dispersed in the buffer chamber 237 and is not directly blown onto the rod-shaped electrodes 269 to 271, thereby suppressing generation of particles. As with the gas supply hole 250a, a plurality of gas supply holes 250b may be formed between the lower portion of the reaction tube 203 and the upper portion thereof.

In this way, in the present embodiments, a gas is transferred via the nozzles 249a and 249b and the buffer chamber 237 arranged in an annular longitudinal space, that is, a cylindrical space, in a plan view defined by the inner wall of the side wall of the reaction tube 203 and the ends of the plurality of wafers 200 arranged in the reaction tube 203. Then, the gas is ejected into the reaction tube 203 near the wafers 200 for the first time from the gas supply holes 250a and 250b formed in the nozzles 249a and 249b and the gas supply ports 302 and 304 formed in the buffer chamber 237. The main flow of the gas in the reaction tube 203 is in a direction parallel to the surfaces of the wafers 200, that is, in a horizontal direction. With such a configuration, the gas can be uniformly supplied to each wafer 200, so that the uniformity of film thickness formed on each wafer 200 can be improved. A gas flowing on the surfaces of the wafers 200, that is, the residual gas after reaction flows toward an exhaust port, that is, an exhaust pipe 231 to be described below. However, the direction of the flow of the residual gas is appropriately specified depending on the position of the exhaust port, and is not limited to the vertical direction.

A precursor containing a predetermined element, for example, a silane precursor gas containing silicon (Si) as the predetermined element, is supplied from the gas supply pipe 232a into the process chamber 201 via the MFC 241a, the valve 243a, and the nozzle 249a.

A precursor gas refers to a gaseous precursor, for example, a gas obtained by vaporizing a precursor in a liquefied state at normal temperature and normal pressure, a precursor in a gaseous state at normal temperature and normal pressure, and the like. When the term “precursor” is used herein, it may indicate a case of including a “liquid precursor in a liquefied state,” a case of including a “precursor gas in a gaseous state,” or a case of including both of them.

An example of the silane precursor gas may include a precursor gas containing Si and a halogen element, that is, a halosilane precursor gas. The halosilane precursor is a silane precursor including a halogen group. The halogen element includes at least one selected from the group consisting of chlorine (Cl), fluorine (F), bromine (Br), and iodine (I). That is, the halosilane precursor includes at least one halogen group selected from the group consisting of a chloro group, a fluoro group, a bromo group, and an iodo group. The halosilane precursor can be said to be a kind of halide.

An example of the halosilane precursor gas may include a precursor gas containing Si and Cl, that is, a chlorosilane precursor gas. An example of the chlorosilane precursor gas may include a dichlorosilane (SiH₂Cl₂, abbreviation: DCS) gas.

A reactant containing an element different from the above-mentioned predetermined element, for example, a nitrogen (N)-containing gas as a reaction gas, is supplied from the gas supply pipe 232b into the process chamber 201 via the MFC 241b, the valve 243b, and the nozzle 249b. An example of the N-containing gas may include a hydrogen nitride-based gas. The hydrogen nitride-based gas can be said to be a substance composed of only two elements of N and H, and acts as a nitriding gas, that is, a N source. An example of the hydrogen nitride-based gas may include an ammonia (NH₃) gas.

An inert gas, for example, a nitrogen (N₂) gas, is supplied from the gas supply pipes 232c and 232d into the process chamber 201 via the MFCs 241c and 241d, the valves 243c and 243d, the gas supply pipes 232a and 232b, and the nozzles 249a and 249b, respectively.

A precursor supply system as a first gas supply system mainly includes the gas supply pipe 232a, the MFC 241a, and the valve 243a. A reactant supply system as a second gas supply system mainly includes the gas supply pipe 232b, the MFC 241b, and the valve 243b. An inert gas supply system mainly includes the gas supply pipes 232c and 232d, the MFCs 241c and 241d, and the valves 243c and 243d. The precursor supply system, the reactant supply system, and the inert gas supply system are collectively referred to simply as a gas supply system (gas supply part).

### (Plasma Generation Part)

As illustrated in FIGS. 2, 3A, and 3B, three rod-shaped electrodes 269, 270, and 271, which are made of a conductor and have an elongated structure, are disposed in the buffer chamber 237 along the stack direction of the wafers 200 from the lower portion of the reaction tube 203 to the upper portion thereof. Each of the rod-shaped electrodes 269, 270, and 271 is installed parallel to the nozzle 249b. Each of the rod-shaped electrodes 269, 270, and 271 is covered with and protected by an electrode protection tube 275 over a region from an upper portion to a lower portion thereof. Among the rod-shaped electrodes 269, 270, and 271, the rod-shaped electrodes 269 and 271 disposed at both ends are connected to a high frequency power supply 273 having a frequency of, for example, 27MHz via a matching device 272. The rod-shaped electrode 270 is grounded to the ground that is the reference potential. That is, the rod-shaped electrodes connected to the high frequency power supply 273 and the grounded rod-shaped electrode are alternately arranged. The rod-shaped electrode 270 interposed between the rod-shaped electrodes 269 and 271 connected to the high frequency power supply 273 is used in common for the rod-shaped electrodes 269 and 271 as the grounded rod-shaped electrode. In other words, the grounded rod-shaped electrode 270 is disposed so as to be sandwiched between the rod-shaped electrodes 269 and 271 connected to the adjacent high frequency power supply 273, and the rod-shaped electrode 269 and the rod-shaped electrode 270, and similarly the rod-shaped electrode 271 and the rod-shaped electrode 270, are configured to be paired to generate plasma. That is, the grounded rod-shaped electrode 270 is used in common for the rod-shaped electrodes 269 and 271 connected to two high frequency power supplies 273 adjacent to the rod-shaped electrode 270. By applying high frequency (RF) power from the high frequency power supply 273 to the rod-shaped electrodes 269 and 271, plasma is generated in a plasma generation region 224a between the rod-shaped electrodes 269 and 270 and in a plasma generation region 224b between the rod-shaped electrodes 270 and 271. A plasma generation part (plasma generator) as a plasma source mainly includes the rod-shaped electrodes 269, 270, and 271 and the electrode protection tubes 275. The plasma source may include the matching device 272 and the high frequency power supply 273. As will be described below, the plasma source functions as a plasma excitation part (an activation mechanism) that plasma-excites a gas, namely, excites (activates) a gas into a plasma state.

Each electrode protection tube 275 has a structure in which each of the rod-shaped electrodes 269, 270, and 271 can be inserted into the buffer chamber 237 while keeping each of the rod-shaped electrodes 269, 270, and 271 isolated from the internal atmosphere of the buffer chamber 237. If an 0₂ concentration within the electrode protection tube 275 is substantially equal to an 0₂ concentration in the outside air (atmosphere), each of the rod-shaped electrodes 269, 270, and 271 inserted into the electrode protection tube 275 may be oxidized by the heat generated from the heater 207. For this reason, by charging the interior of the electrode protection tube 275 with an inert gas such as a N₂ gas or the like, or by purging the interior of the electrode protection tube 275 with an inert gas such as a N₂ gas or the like through the use of an inert gas purge mechanism, it is possible to reduce the O₂ concentration within the electrode protection tube 275, thereby preventing oxidation of the rod-shaped electrodes 269, 270, and 271.

An exhaust pipe 231 for exhausting an internal atmosphere of the process chamber 201 is installed at the reaction tube 203. A vacuum pump 246, as a vacuum-exhausting device, is connected to the exhaust pipe 231 via a pressure sensor 245, which is a pressure detector (pressure detecting part) for detecting an internal pressure of the process chamber 201, and an APC (auto pressure controller) valve 244, which is an exhaust valve (pressure adjustment part). The APC valve 244 is configured to perform or stop a vacuum-exhausting operation in the process chamber 201 by opening or closing the valve while the vacuum pump 246 is actuated, and is also configured to adjust the internal pressure of the process chamber 201 by adjusting an opening degree of the valve based on pressure information detected by the pressure sensor 245 while the vacuum pump 246 is actuated. An exhausting system mainly includes the exhaust pipe 231, the APC valve 244, and the pressure sensor 245. The exhausting system may include the vacuum pump 246. The exhaust pipe 231 is not limited to being installed at the reaction tube 203, but may be installed at the manifold 209 in the same manner as the nozzles 249a and 249b.

A seal cap 219, which serves as a furnace opening cover configured to hermetically seal a lower end opening of the manifold 209, is installed under the manifold 209. The seal cap 219 is configured to contact the lower end of the manifold 209 from the lower side in the vertical direction. The seal cap 219 is made of, for example, a metal material such as stainless steel (SUS) or the like, and is formed in a disc shape. An 0-ring 220b, which is a seal member making contact with the lower end of the manifold 209, is installed at an upper surface of the seal cap 219. A rotation mechanism 267 configured to rotate a boat 217, which will be described below, is installed at the opposite side of the seal cap 219 from the process chamber 201. A rotary shaft 255 of the rotation mechanism 267, which penetrates through the seal cap 219, is connected to the boat 217. The rotation mechanism 267 is configured to rotate the wafers 200 by rotating the boat 217. The seal cap 219 is configured to be vertically moved up and down by a boat elevator 115 which is an elevator mechanism vertically installed outside the reaction tube 203. The boat elevator 115 is configured so as to load/unload the boat 217 into/out of the process chamber 201 by moving the seal cap 219 up and down. The boat elevator 115 is configured as a transfer device (transfer mechanism) which transfers the boat 217, that is, the wafers 200, into/out of the process chamber 201. In addition, a shutter 219s, which serves as a furnace opening cover configured to hermetically seal a lower end opening of the manifold 209 while the seal cap 219 is descended by the boat elevator 115, is installed under the manifold 209. The shutter 219s is made of, for example, a metal material such as stainless steel (SUS) or the like, and is formed in a disc shape. An 0-ring 220c, which is a seal member making contact with the lower end of the manifold 209, is installed at an upper surface of the shutter 219s. The opening/closing operation (such as elevation operation, rotation operation, or the like) of the shutter 219s is controlled by a shutter-opening/closing mechanism 115s.

### (Substrate Support)

As illustrated in FIG. 1, the boat 217 serving as a substrate support (substrate support part) is configured to support a plurality of wafers 200, for example, 25 to 200 wafers, in such a state that the wafers 200 are arranged in a horizontal posture and in multiple stages along a vertical direction with the centers of the wafers 200 aligned with one another. As such, the boat 217 is configured to arrange the wafers 200 to be spaced apart from each other. The boat 217 is made of a heat resistant material such as quartz or SiC. Heat-insulating plates 218 made of a heat resistant material such as quartz or SiC are supported in multiple stages below the boat 217.

As illustrated in FIG. 2, a temperature sensor 263 serving as a temperature detector is installed in the reaction tube 203. Based on temperature information detected by the temperature sensor 263, a state of supplying electric power to the heater 207 is adjusted such that the interior of the process chamber 201 has a desired temperature distribution. The temperature sensor 263 is installed along the inner wall of the reaction tube 203 in the same manner as the nozzles 249a and 249b.

### (Control Device)

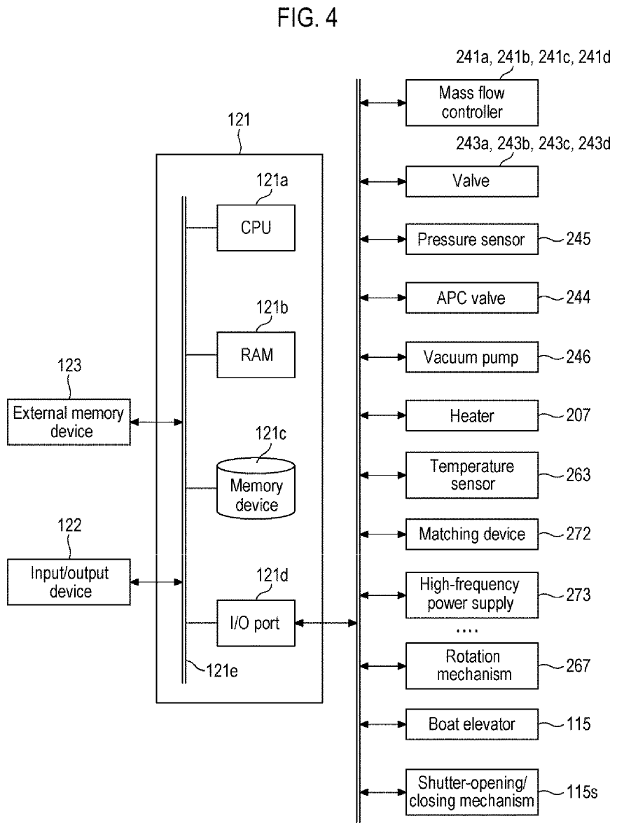

Next, a control device will be described with reference to FIG. 4. As illustrated in FIG. 4, a controller 121, which is a control part (control device), may be configured as a computer including a CPU (central processing unit) 121a, a RAM (random access memory) 121b, a memory device 121c, and an I/O port 121d. The RAM 121b, the memory device 121c, and the I/O port 121d are configured to exchange data with the CPU 121a via an internal bus 121e. An input/output device 122 formed of, e.g., a touch panel or the like, is connected to the controller 121.

The memory device 121c is configured by, for example, a flash memory, a HDD (hard disk drive), or the like. A control program for controlling operations of a substrate processing apparatus and a process recipe, in which sequences and conditions of a film-forming process to be described below are written, are readably stored in the memory device 121c. The process recipe functions as a program for causing the controller 121 to execute each sequence in various kinds of processes (film-forming processes), which will be described below, to obtain an expected result. Hereinafter, the process recipe and the control program may be generally and simply referred to as a “program.” Furthermore, the process recipe may be simply referred to as a “recipe.” When the term “program” is used herein, it may indicate a case of including the recipe only, a case of including the control program only, or a case of including both the recipe and the control program. The RAM 121b is configured as a memory area (work area) in which a program or data read by the CPU 121a is temporarily stored.

The I/O port 121d is connected to the MFCs 241a to 241d, the valves 243a to 243d, the pressure sensor 245, the APC valve 244, the vacuum pump 246, the heater 207, the temperature sensor 263, the matching device 272, the high frequency power supply 273, the rotation mechanism 267, the boat elevator 115, the shutter-opening/closing mechanism 115s, a first tank 331a, a second tank 331b, a first pressure gauge 332a, a second pressure gauge 332b, a first valve 333a, a second valve 333b, a first air operate valve 334a, a second air operate valve 334b, a pressure regulator 345, and the like.

The CPU 121a is configured to read and execute the control program from the memory device 121c. The CPU 121a is also configured to read the recipe from the memory device 121c according to an input of an operation command from the input/output device 122. In addition, the CPU 121a is configured to control the rotation mechanism 267, the flow rate adjustment operation of various kinds of gases by the MFCs 241a to 241d, the opening/closing operation of the valves 243a to 243d, the adjustment operation of the high frequency power supply 273 based on impedance monitoring, the opening/closing operation of the APC valve 244, the pressure-regulating operation performed by the APC valve 244 based on the pressure sensor 245, the actuating and stopping of the vacuum pump 246, the temperature adjustment operation performed by the heater 207 based on the temperature sensor 263, the forward/backward rotation, rotation angle and rotation speed adjustment operation of the boat 217 by the rotation mechanism 267, the operation of moving the boat 217 up and down by the boat elevator 115, the heating operation of the first tank 331a and the second tank 331b, the opening/closing operation of the first valve 333a based on the first pressure gauge 332a, the opening/closing operation of the second valve 333b based on the second pressure gauge 332b, the opening/closing operation of the first air operate valve 334a and the second air operate valve 334b, the pressure-regulating operation of the pressure regulator 345, and the like, according to contents of the read recipe.

The controller 121 may be configured by installing, on the computer, the aforementioned program stored in an external memory device 123 (for example, a magnetic disk such as a HDD, an optical disc such as a CD, a magneto-optical disc such as a MO, or a semiconductor memory such as a USB memory). The memory device 121c or the external memory device 123 is configured as a non-transitory computer-readable recording medium. Hereinafter, the memory device 121c and/or the external memory device 123 may be generally and simply referred to as a “recording medium.” When the term “recording medium” is used herein, it may indicate a case of including the memory device 121c only, a case of including the external memory device 123 only, or a case of including both the memory device 121c and the external memory device 123. Furthermore, the program may be provided to the computer using communication means such as the Internet or a dedicated line, instead of using the external memory device 123.

### (2) Substrate-Processing Process

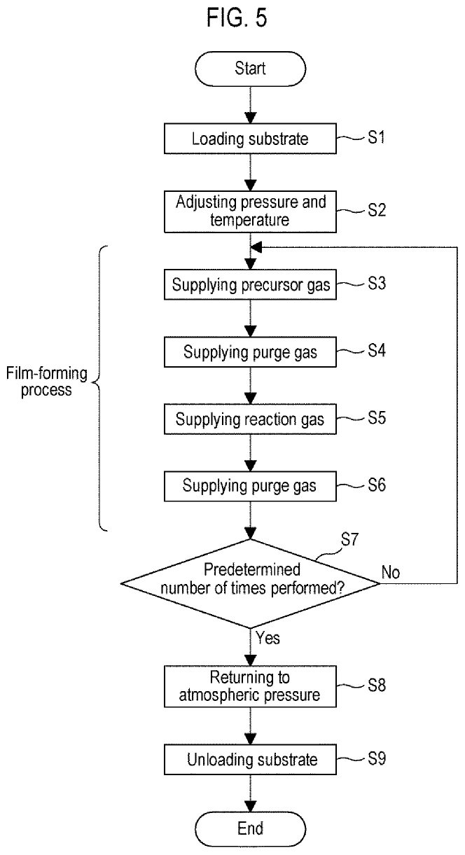

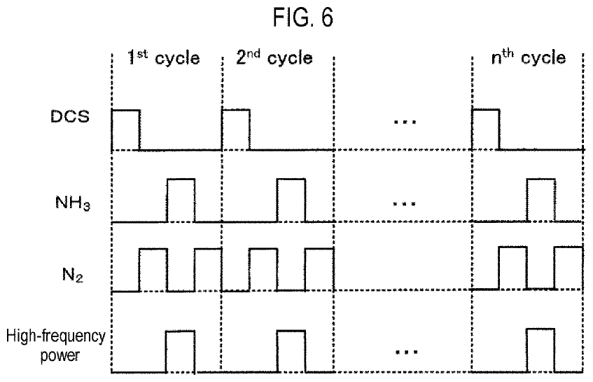

Next, as one of processes of manufacturing a semiconductor device, a process of forming a thin film on a wafer 200 using the substrate processing apparatus will be described with reference to FIGS. 5 and 6. In the following descriptions, the operations of the respective parts constituting the substrate processing apparatus are controlled by the controller 121.

Here, an example will be described in which a silicon nitride film (SiN film) is formed, as a film containing Si and N, on a wafer 200 by, asynchronously, that is, without being synchronized, a predetermined number of times (once or more), performing a step of supplying a DCS gas as a precursor gas and a step of supplying a plasma-excited NH₃ gas as a reaction gas. For example, a predetermined film may be formed in advance on the wafer 200. A predetermined pattern may be formed in advance on the wafer 200 or the predetermined film.

In the present disclosure, for the sake of convenience, a flow of the film-forming process illustrated in FIG. 6 may be denoted as follows.

(DCS→NH₃*)×n⇒SiN

When the term “wafer” is used in the present disclosure, it may refer to “a wafer itself” or “a wafer and a laminated body of certain layers or films formed at a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

### (Loading Step: S1)

When a plurality of wafers 200 is charged on the boat 217 (wafer charging), the shutter 219s is moved by the shutter-opening/closing mechanism 115s, and the lower end opening of the manifold 209 is opened (shutter open). Thereafter, as illustrated in FIG. 1, the boat 217 supporting the plurality of wafers 200 is lifted up by the boat elevator 115 to be loaded into the process chamber 201 (boat loading). In this state, the seal cap 219 seals the lower end of the manifold 209 via the 0-ring 220b.

### (Pressure and Temperature Adjusting Step: S2)

The interior of the process chamber 201, namely, the space in which the wafers 200 are placed, is vacuum-exhausted (depressurization-exhausted) by the vacuum pump 246 so as to reach a desired pressure (degree of vacuum). In this operation, the internal pressure of the process chamber 201 is measured by the pressure sensor 245. The APC valve 244 is feedback-controlled based on the measured pressure information. The vacuum pump 246 keeps operating at all times at least until a film forming step to be described below is completed.

In addition, the wafers 200 in the process chamber 201 are heated by the heater 207 to a desired temperature. In this operation, the state of supplying electric power to the heater 207 is feedback-controlled based on the temperature information detected by the temperature sensor 263 such that the interior of the process chamber 201 has a desired temperature distribution. The heating of the interior of the process chamber 201 by the heater 207 is continuously performed at least until the film forming step to be described below is completed. However, when the film forming step is performed under the temperature condition of equal to or lower than room temperature, the heating of the interior of the process chamber 201 by the heater 207 may not be performed. In the case where only the process at such a temperature is performed, the heater 207 becomes unnecessary. That is, the heater 207 does not need to be installed in the substrate processing apparatus. This contributes to simplification of the configuration of the substrate processing apparatus.

Subsequently, rotation of the boat 217 and the wafer 200 by the rotation mechanism 267 is started. The rotation of the boat 217 and the wafer 200 by the rotation mechanism 267 is continuously performed at least until the film forming step is completed.

### (Precursor Gas Supplying Step: S3 and S4)

At step S3, a DCS gas is supplied to the wafer 200 in the process chamber 201.

The valve 243a is opened to allow the DCS gas to flow into the gas supply pipe 232a. A flow rate of the DCS gas is adjusted by the MFC 241a, and then the DCS gas is supplied from the gas supply hole 250a into the process chamber 201 via the nozzle 249a and is exhausted through the exhaust pipe 231. At the same time, the valve 243c is opened to allow a N₂ gas to flow into the gas supply pipe 232c. A flow rate of the N₂ gas is adjusted by the MFC 241c, and the N₂ gas is supplied into the process chamber 201 together with the DCS gas and is exhausted through the exhaust pipe 231.

In addition, in order to prevent the DCS gas from infiltrating into the nozzle 249b, the valves 243d is opened to allow a N₂ gas to flow into the gas supply pipe 232d. The N₂ gas is supplied into the process chamber 201 through the gas supply pipe 232b and the nozzle 249b and is exhausted through the exhaust pipe 231.

A supply flow rate of the DCS gas, which is controlled by the WC 241a, is set to fall within a range of, e.g., 1 sccm or larger and 6,000 sccm or smaller, specifically, 3,000 or larger and 5,000 sccm or smaller. Supply flow rates of the N₂ gas, which are controlled by the MFCs 241c and 241d, are set to fall within a range of, e.g., 100 sccm or larger and 10,000 sccm or smaller. The internal pressure of the process chamber 201 is set to fall within a range of, e.g., 1 Pa or higher and 2,666 Pa or lower, specifically, 665 Pa or higher and 1,333 Pa or lower. A time period during which the wafer 200 is exposed to the DCS gas is set to, e.g., about 20 seconds per cycle. The time period during which the wafer 200 is exposed to the DCS gas is varied depending on film thickness.

The temperature of the heater 207 is set such that the temperature of the wafer 200 falls within a range of, e.g., 0 degrees C. or higher and 700 degrees C. or lower, specifically, room temperature (25 degrees C.) or higher and 550 degrees C. or lower, more specifically, 40 degrees C. or higher and 500 degrees C. or lower. As the present embodiments, the amount of heat applied to the wafer 200 can be reduced by setting the temperature of the wafer 200 to 700 degrees C. or lower, further 550 degrees C. or lower, and furthermore 500 degrees C. or less, and accordingly, the heat history received by the wafer 200 can be satisfactorily controlled.

By supplying the DCS gas to the wafer 200 under the aforementioned conditions, a Si-containing layer is formed on the wafer 200 (surface base film). The Si-containing layer may be a Si layer containing Cl or H. The Si-containing layer is formed at the outermost surface of the wafer 200 to which DCS is physically adsorbed, a substance obtained by partial decomposition of DCS is chemically adsorbed, or Si is deposited by thermal decomposition of DCS. That is, the Si-containing layer may be an adsorption layer (physical adsorption layer or chemical adsorption layer) of DCS or a substance obtained by partial decomposition of DCS, or a Si deposition layer (Si layer).

### (Purge Gas Supplying Step: S4)

After the Si-containing layer is formed, the valve 243a is closed and the supply of the DCS gas into the process chamber 201 is stopped. At this time, the APC valve 244 is kept open, the interior of the process chamber 201 is vacuum-exhausted by the vacuum pump 246, and the unreacted DCS gas or the DCS gas, which has been contributed to the formation of the Si-containing layer, and the reaction byproducts remaining in the process chamber 201 are removed from the interior of the process chamber 201 (S4). Further, the supply of the N₂ gas into the process chamber 201 is maintained while the valves 243c and 243d remain open. The N₂ gas acts as a purge gas (an inert gas). Further, the step S4 may be omitted.

As the precursor gas, in addition to the DCS gas, it may be possible to suitably use, e.g., various aminosilane precursor gases such as a tetrakisdimethylaminosilane (Si[N(CH₃)₂]₄, abbreviation: 4DMAS) gas, a tri sdimethylaminosilane (Si[N(CH₃)₂]₃H, abbreviation: 3DMAS) gas, a bisdimethylaminosilane (Si[N(CH₃)₂]₂H₂, abbreviation: BDMAS) gas, a bisdiethylaminosilane (Si[N(C₂H₅)_{z}]₂H₂, abbreviation: BDEAS) gas, a bistertiarybutylaminosilane (SiH₂[NH(C₄H₉)]₂, abbreviation: BTBAS) gas, a dimethylaminosilane (abbreviation: DMAS) gas, a diethylaminosilane (abbreviation: DEAS) gas, a dipropylaminosilane (abbreviation: DPAS) gas, a diisopropylaminosilane (abbreviation: DIPAS) gas, a butylaminosilane (abbreviation: BAS) gas, a hexamethyldisilazane (abbreviation: HMDS) gas, and the like, inorganic halosilane precursor gases such as a monochlorosilane (SiH₃Cl, abbreviation: MCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas, and the like, and halogen group-free inorganic silane precursor gases such as a monosilane (SiH₄, abbreviation: MS) gas, a disilane (Si₂H₆, abbreviation: DS) gas, a trisilane (Si₃H₈, abbreviation: TS) gas, and the like.

Examples of the inert gas may include rare gases such as an Ar gas, a He gas, a Ne gas, a Xe gas, and the like, in addition to the N₂ gas.

### (Reaction Gas Supplying Step: S5 and S6)

After the film-forming process is completed, a plasma-excited NH₃ gas as a reaction gas is supplied to the wafer 200 in the process chamber 201 (S5).

In this step, the opening/closing control of the valves 243b to 243d is performed in the same procedure as the opening/closing control of the valves 243a, 243c, and 243d in step S3. A flow rate of the NH₃ gas is adjusted by the WC 241b, and the NH₃ gas is then supplied into the buffer chamber 237 through the nozzle 249b. At this time, high frequency power is supplied between the rod-shaped electrodes 269, 270, and 271. The NH₃ gas supplied into the buffer chamber 237 is excited into a plasma state (plasmarized and activated), supplied as active species (NH₃*) into the process chamber 201, and exhausted through the exhaust pipe 231.

A supply flow rate of the NH₃ gas, which is controlled by the WC 241b, is set to fall within a range of, e.g., 100 or larger and 10,000 sccm or smaller, specifically, 1,000 or larger and 2,000 sccm or smaller. The high frequency power applied to the rod-shaped electrodes 269, 270, and 271 is set to fall within a range of, e.g., 50 W or larger and 600 W or lower. The internal pressure of the process chamber 201 is set to fall within a range of, e.g., 1 Pa or higher and 500 Pa or lower. By using plasma, the NH₃ gas can be activated even when the internal pressure of the process chamber 201 is set to such a relatively low pressure zone. The time for supplying the active species obtained by plasma excitation of the NH₃ gas to the wafer 200, that is, the gas supply time (irradiation time), is set to fall within a range of, e.g., 1 second or longer and 180 seconds or shorter, specifically, 1 second or longer and 60 seconds or shorter. Other process conditions are the same as those in step S3 described above.

By supplying the NH₃ gas to the wafer 200 under the aforementioned conditions, the Si-containing layer formed on the wafer 200 is plasma-nitrided. At this time, the Si-Cl bond and Si-H bond of the Si-containing layer are cut by the energy of the plasma-excited NH₃ gas. Cl and H de-bonded from Si are desorbed from the Si-containing layer. Then, Si in the Si-containing layer, which has a dangling bond due to the desorption of Cl or the like, is bonded to N contained in the NH₃ gas to form a Si-N bond. As this reaction proceeds, the Si-containing layer is changed (modified) into a layer containing Si and N, namely, a silicon nitride layer (SiN layer).

In order to modify the Si-containing layer into the SiN layer, it is necessary to supply the NH₃ gas after being plasma-excited. This is because, even if the NH₃ gas is supplied in a non-plasma atmosphere, the energy necessary for nitriding the Si-containing layer is insufficient in the above-mentioned temperature zone, and accordingly, it is difficult to increase the Si-N bond by sufficiently desorbing Cl and H from the Si-containing layer or sufficiently nitriding the Si-containing layer.

### (Purge Gas Supplying Step: S6)

After the Si-containing layer is changed into the SiN layer, the valve 243b is closed and the supply of the NH₃ gas is stopped. In addition, the supply of high frequency power between the rod-shaped electrodes 269, 270, and 271 is stopped. Then, the NH₃ gas and reaction byproducts remaining in the process chamber 201 are removed from the process chamber 201 (S6) according to the same processing procedure and process conditions as in step S4. Further, the step S6 may be omitted.

As a nitriding agent, that is, a plasma-excited N-containing gas, in addition to the NH₃ gas, it may be possible to use, e.g., a diazene (N₂H₂) gas, a hydrazine (N₂H₄) gas, a N₃H₈ gas, or the like.

As an inert gas, for example, various rare gases exemplified in step S4 may be used in addition to the N₂ gas.

### (Performing Predetermined Number of Times: S7)

A cycle that non-simultaneously (i.e., asynchronously) performs steps S3, S4, S5, and S6 sequentially is performed a predetermined number of times (n times), that is, once or more (S7), to thereby form a SiN film having a predetermined composition and a predetermined film thickness on the wafer 200. This cycle may be repeated multiple times. That is, a thickness of the SiN layer formed per one cycle may be set to be smaller than a desired film thickness. Thus, the above cycle may be repeated multiple times until a film thickness of the SiN film formed by laminating the SiN layers becomes equal to the desired film thickness.

### (Returning to Atmospheric Pressure Step: S8)

After the above-described film-forming process is completed, a N₂ gas as an inert gas is supplied into the process chamber 201 from each of the gas supply pipes 232c and 232d and is exhausted through the exhaust pipe 231. Thus, the interior of the process chamber 201 is purged by the inert gas to remove the gas and the like remaining in the process chamber 201 from the interior of the process chamber 201 (inert gas purge). The internal atmosphere of the process chamber 201 is then substituted with the inert gas (inert gas substitution) and the internal pressure of the process chamber 201 is returned to an atmospheric pressure (S8).

### (Unloading Step: S9)

The seal cap 219 is then moved down by the boat elevator 115 to open the lower end of the manifold 209. In addition, the processed wafers 200 supported by the boat 217 are unloaded from the lower end of the manifold 209 to the outside of the reaction tube 203 (boat unloading) (S9). After the boat unloading, the shutter 219s is moved, and the lower end opening of the manifold 209 is sealed by the shutter 219s via the 0-ring 220c (shutter closing). After being unloaded from the reaction tube 203, the processed wafers 200 are discharged from the boat 217 (wafer discharging). After the wafer discharging, an empty boat 217 may be loaded into the process chamber 201.

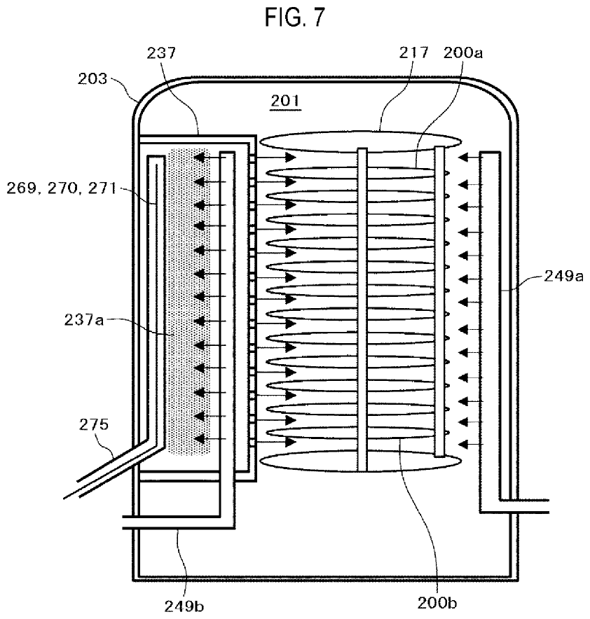

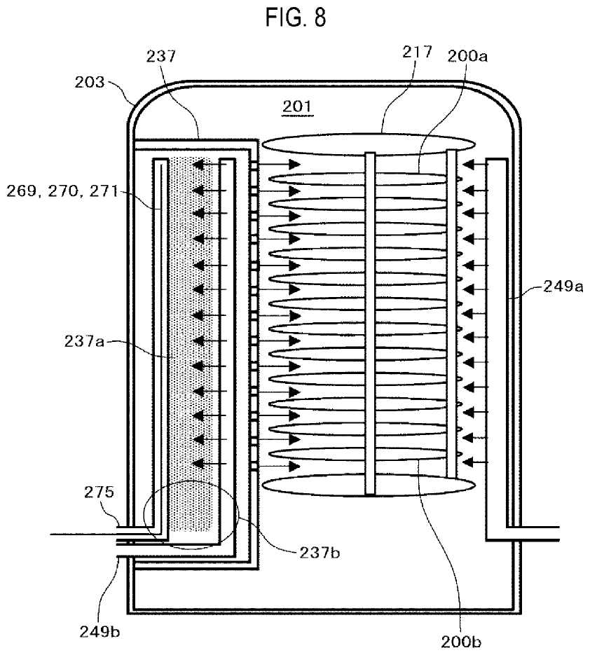

Next, the effects of the buffer chamber 237 in the above-described step S5 will be described with reference to FIGS. 6 to 9. FIGS. 7 and 8 illustrate a case where the NH₃ gas is supplied from the nozzle 249b into the buffer chamber 237, is excited into the plasma state by the high-frequency power supplied between the rod-shaped electrodes 269, 270, and 271 and is supplied as the active species (NH₃*) gas into the process chamber 201, and the N₂ gas is supplied from the nozzle 249a into the process chamber 201 in order to prevent the active species gas from entering the nozzle 249a. In FIGS. 7 and 8, the directions of arrows indicate the directions in which the gases flow.

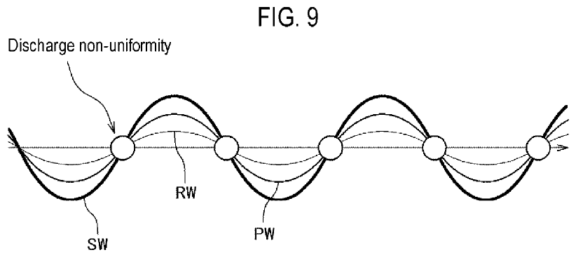

Although a power supply having a frequency of 13.56 MHz is often used in the plasma generator, a power supply having a frequency of 27 MHz (27 MHz±1.0%, for example, 27.12 MHz) can be employed in order to improve the plasma density. However, when the power supply of 27 MHz is employed, as illustrated in the comparative example of FIG. 8, a standing wave SW is generated at a plasma generation region 237a below the buffer chamber 237 in a reaction tube shape in which the bottom surface of the buffer chamber 237 extends below the nozzle 249b, which results in unstable discharge to make the plasma density non-uniform. A region where the standing wave SW is generated is called a standing wave generation region 237b. When the plasma becomes non-uniform, the supply of the active species gas to the wafer becomes unstable, which may cause problems in film thickness uniformity, WER, and the like with respect to wafer film formation. As illustrated in FIG. 9, the plasma source has a resonance structure of a traveling wave PW and a reflected wave RW, and a wave obtained by resonance is called a standing wave SW. The discharge non-uniformity depends on a frequency. As the frequency increases, a distance at which the discharge non-uniformity (indicated by open circles in FIG. 9) periodically occurs becomes shorter.

In the present embodiments, in order to prevent plasma from being generated in the standing wave generation region 237b below the buffer chamber 237 as illustrated in FIG. 8, as illustrated in FIG. 7, the buffer chamber 237 is formed along the inner wall of the reaction tube 203 at a height between the lowermost wafer 200b and the uppermost wafer 200a supported by the boat 217, and the bottom surface of the buffer chamber 237 is lifted up to a position of the upper heat-insulating plate supported by the lower portion of the boat 217. Further, the electrode protection tube 275 is inserted from below the buffer chamber 237 through the side surface of the reaction tube 203, and the nozzle 249b is inserted from the bottom surface of the buffer chamber 237 through the side surface of the reaction tube 203. When the electrode protection tube 275 penetrates the side surface of the reaction tube 203, the position of the electrode protection tube 275 at the inner side of the reaction tube 203 is higher than the position thereof at the outer side of the reaction tube 203. Thus, when the lower portion of the buffer chamber 237 is set at the position of the lowermost wafer 200b supported by the boat 217 and the upper portion of the buffer chamber 237 is set at the position of the uppermost wafer 200a supported by the boat 217, the buffer chamber can be minimized, and the effect of a standing wave generated at 27 MHz (discharge non-uniformity) can be reduced.

Note that, similarly to the nozzle 249b, the electrode protection tube 275 may be inserted from the bottom surface of the buffer chamber 237 through the side surface of the reaction tube 203.

Some embodiments of the present disclosure have been described in detail above. However, the present disclosure is not limited to the above-described embodiments but may be differently modified without departing from the subject matter of the present disclosure.

For example, an example in which the reaction gas is supplied after the precursor is supplied has been described in the above embodiments. The present disclosure is not limited to such an aspect, and the supply order of the precursor and the reaction gas may be reversed. That is, the precursor may be supplied after the reaction gas is supplied. By changing the supply order, the film quality and composition ratio of the film to be formed can be changed.

An example in which the SiN film is formed on the wafer 200 has been described in the above embodiments and the like. The present disclosure is not limited to such an aspect but may be suitably applied to a case of forming a Si-based oxide film such as a silicon oxide film (SiO film), a silicon oxycarbide film (SiOC film), a silicon oxycarbonitride film (SiOCN film), a silicon oxynitride film (SiON film) or the like on the wafer 200, and a case of forming a Si-based nitride film such as a silicon carbonitride film (SiCN film), a silicon boronitride film (SiBN film), a silicon borocarbonitride film (SiBCN film) or the like on the wafer 200. In these cases, in addition to the O-containing gas, a C-containing gas such as C₃H₆ or the like, a N-containing gas such as NH₃ or the like, or a B-containing gas such as BCl₃ or the like may be used as the reaction gas.

In addition, the present disclosure may be suitably applied to a case of forming an oxide film or a nitride film containing a metal element such as titanium (Ti), zirconium (Zr), hafnium (Hf), tantalum (Ta), niobium (Nb), aluminum (Al), molybdenum (Mo), tungsten (W), or the like, that is, a metal-based oxide film or a metal-based nitride film, on the wafer 200. That is, the present disclosure may be suitably applied to a case of forming a TiO film, a TiN film, a TiOC film, a TiOCN film, a TiON film, a TiBN film, a TiBCN film, a ZrO film, a ZrN film, a ZrOC film, a ZrOCN film, a ZrON film, a ZrBN film, a ZrBCN film, a HfO film, a HfN film, a HfOC film, a HfOCN film, a HfON film, a HfBN film, a HfBCN film, a TaO film, a TaOC film, a TaOCN film, a TaON film, a TaBN film, a TaBCN film, a NbO film , a NbN film, a NbOC film, a NbOCN film, a NbON film, a NbBN film, a NbBCN film, an AlO film, an AN film, an AlOC film, an AlOCN film, an AlON film, an AlBN film, an AlBCN film, a MoO film, a MoN film, a MoOC film, a MoOCN film, a MoON film, a MoBN film, a MoBCN film, a WO film, a WN film, a WOC film, a WOCN film, a WON film, a MWBN film, a WBCN film, or the like on the wafer 200.

In this case, as the precursor gas, it may be possible to use, e.g., a tetrakis(dimethylamino)titanium (Ti[N(CH₃)₂]₄, abbreviation: TDMAT) gas, a tetrakis(ethylmethylamino)hafnium (Hf[N(C₂H₅)(CH₃)]₄, abbreviation: TEMAH) gas, a tetrakis(ethylmethylamino)zirconium (Zr[N(C₂H₅)(CH₃)]₄, abbreviation: TEMAZ) gas, a trimethylaluminum (Al(CH₃)₃, abbreviation: TMA) gas, a titaniumtetrachloride (TiCl₄) gas, a hafniumtetrachloride (HfCl₄) gas, or the like. As the reaction gas, the above-mentioned reaction gas can be used.

That is, the present disclosure can be suitably applied to a case of forming a half metal-based film containing a half metal element or a metal-based film containing a metal element. The processing procedures and processing conditions of this film-forming process may be the same as those of the film-forming processes described in the above-described embodiments and modifications. Even in this case, the same effects as those of the above-described embodiments and modifications can be obtained.

Recipes used in the film-forming process may be prepared individually according to the processing contents and may be stored in the memory device 121c via a telecommunication line or the external memory device 123. Moreover, at the beginning of various types of processes, the CPU 121a may properly select an appropriate recipe from the recipes stored in the memory device 121c according to the contents of the processing. Thus, it is possible for a single substrate processing apparatus to form films of various kinds, composition ratios, qualities, and thicknesses for general purpose and with enhanced reproducibility. In addition, it is possible to reduce an operator's burden and to quickly start the various types of processes while avoiding an operation error.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the substrate processing apparatus may be directly modified by operating the input/output device 122 of the substrate processing apparatus.

According to the present disclosure in some embodiments, it is possible to provide a technique capable of processing a substrate uniformly

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a reaction tube configured to process a plurality of substrates;
a substrate support configured to support the plurality of substrates stacked in multiple stages;
a buffer chamber that is at least located at a position of height from a lowermost substrate to an uppermost substrate supported by the substrate support, and is installed along an inner wall of the reaction tube; and
an electrode for plasma generation that is inserted from a lower portion of the buffer chamber into an upper portion of the buffer chamber through a side surface of the reaction tube, the electrode being configured to activate the processing gas by plasma inside the buffer chamber thereby applying high-frequency power to the electrode by a power supply.

2. The substrate processing apparatus of claim 1, wherein a gas supply hole for supplying the activated processing gas to a center of the reaction tube is installed at the buffer chamber.

3. The substrate processing apparatus of claim 1, wherein the electrode includes:
a first rod-shaped electrode connected to a high-frequency power supply having a frequency of about 27 MHz; and
a second rod-shaped electrode connected to a reference potential, and
wherein the first rod-shaped electrode and the second rod-shaped electrode are alternately arranged.

4. The substrate processing apparatus of claim 1, wherein the electrode includes:
a plurality of first rod-shaped electrodes connected to a high-frequency power supply having a frequency of about 27 MHz; and
a second rod-shaped electrode connected to a reference potential, between the plurality of first rod-shaped electrodes.

5. The substrate processing apparatus of claim 1, further comprising:
heat-insulating plates formed in multiple stages for supporting the substrate support; and
a high-frequency power supply configured to apply high-frequency power having a frequency of about 27 MHz to the electrode,
wherein a bottom surface of the buffer chamber is located at an upper end of the heat-insulating plates in order to prevent plasma from being generated at a standing wave generation region of the lower portion of the buffer chamber.

6. The substrate processing apparatus of claim 1, further comprising:
an electrode protection tube configured to protect the electrode by covering the electrode,
wherein the electrode protection tube is inserted from the lower portion of the buffer chamber through the side surface of the reaction tube.

7. The substrate processing apparatus of claim 6, wherein the electrode protection tube penetrates the side surface of the reaction tube such that a position of the electrode protection tube at an inner side of the reaction tube is higher than a position of the electrode protection tube at an outer side of the reaction tube.

8. The substrate processing apparatus of claim 6, wherein the electrode is inserted into the electrode protection tube that is inserted from the lower portion of the buffer chamber through the side surface of the reaction tube.

9. The substrate processing apparatus of claim 1, further comprising:
a gas supply part inserted from a bottom surface of the buffer chamber through the side surface of the reaction tube and configured to supply the processing gas into the buffer chamber.

10. The substrate processing apparatus of claim 1, further comprising:
a nozzle configured to supply the processing gas into the buffer chamber,
wherein the nozzle is inserted from a bottom surface of the buffer chamber through the side surface of the reaction tube.

11. The substrate processing apparatus of claim 1, further comprising:
an electrode protection tube configured to protect the electrode by covering the electrode,
wherein the electrode protection tube is inserted from a bottom surface of the buffer chamber through the side surface of the reaction tube.

12. The substrate processing apparatus of claim 1, wherein the processing gas is a nitrogen-containing gas.

13. A method of manufacturing a semiconductor device in a substrate processing apparatus including: a reaction tube configured to process a plurality of substrates, a substrate support configured to support the plurality of substrates stacked in multiple stages, a buffer chamber that is at least located at a position of height from a lowermost substrate to an uppermost substrate supported by the substrate support, and is installed along an inner wall of the reaction tube, and an electrode for plasma generation that is inserted from a lower portion of the buffer chamber into an upper portion of the buffer chamber through a side surface of the reaction tube, the electrode being configured to activate the processing gas by plasma inside the buffer chamber thereby applying high-frequency power to the electrode by a power supply, and the method comprising:
loading the substrates to the reaction tube;
supplying the processing gas into the buffer chamber;
activating the processing gas supplied into the buffer chamber by plasma; and
supplying the processing gas activated by the plasma to the substrates.

14. A non-transitory computer-readable recording medium storing a program that causes, by a computer, a substrate processing apparatus to perform a process, the substrate processing apparatus including: a reaction tube configured to process a plurality of substrates, a substrate support configured to support the plurality of substrates stacked in multiple stages, a buffer chamber that is at least located at a position of height from a lowermost substrate to an uppermost substrate supported by the substrate support, and is installed along an inner wall of the reaction tube, and an electrode for plasma generation that is inserted from a lower portion of the buffer chamber into an upper portion of the buffer chamber through a side surface of the reaction tube, the electrode being configured to activate the processing gas by plasma inside the buffer chamber thereby applying high-frequency power to the electrode by a power supply, and the process comprising:
loading the substrates to the reaction tube;
supplying the processing gas into the buffer chamber;
activating the processing gas supplied into the buffer chamber by plasma; and
supplying the processing gas activated by the plasma to the substrates.
